(19) United States
(12) Patent Application Publication
(10) Pub. No.: US 2026/0259698 A1
(43) Pub. Date: Sep. 3, 2026

(54) FIELD PROGRAMMABLE GATE ARRAY WITH INTEGRATED ANALOG IN-MEMORY COMPUTING DOT PRODUCT

(71) Applicant: Hewlett Packard Enterprise Development LP, Spring, TX (US)

(72) Inventors: Luca Buonanno, Fort Collins, CO (US); Archit Gajjar, Timnath, CO (US); Lei Zhao, Fort Collins, CO (US); Aishwarya Natarajan, Milpitas, CA (US); Omar Khaled Mohamed Mahmoud Eldash, Sunnyvale, CA (US); Giacomo Pedretti, San Francisco, CA (US); Paolo Faraboschi, Palo Alto, CA (US); James Ignowski, Fort Collins, CO (US)

(21) Appl. No.: 19/067,179

(22) Filed: Feb. 28, 2025

(51) Int. Cl. G06F 7/544; G06F 7/523; G06F 17/16; H03M 1/12; H03M 1/66

(52) U.S. Cl. CPC G06F 7/5443; G06F 7/523; G06F 17/16; H03M 1/12; H03M 1/66

(57) ABSTRACT

According to an implementation, a field programmable gate array includes analog dot product engine (DPE) cores integrated alongside configurable logic circuits. Each DPE core includes an array of programmable resistive memory elements arranged in a crossbar configuration that stores matrix weights and performs matrix-vector multiplication in the analog domain. The DPE cores include digital-to-analog converters, analog-to-digital converters, and shift and add circuitry for processing computation results. A memory array coupled to the DPE cores stores input vectors and partial sums, while an interconnect network couples the configurable logic circuits, DPE cores, and memory array. Control circuitry implements pipeline stages comprising read, compute, sum, activation, and write operations to coordinate data flow between components.

### BACKGROUND

Matrix-vector multiplication operations appear throughout computational workloads or applications, from artificial intelligence (AI) and deep neural networks to signal processing applications. These operations typically involve reading data from memory, calculating results using digital logic circuits, and writing outcomes back to memory locations. Moving data between memory and computation circuits consumes significant time and energy in computing systems.

In-memory computing approaches aim to reduce data movement by performing calculations where data resides. Resistive memory arrays may store values as programmable resistances and execute analog domain computations within the memory elements. Dot Product Engines (DPEs) utilize these characteristics to perform matrix-vector multiplications by applying input voltages to rows of resistive elements and measuring output currents corresponding to computation results. The analog nature of these calculations allows multiple operations to occur concurrently within a single array, enhancing speed and energy efficiency.

### BRIEF DESCRIPTION OF THE DRAWINGS

For a more complete understanding of this disclosure, and advantages thereof, reference is now made to the following descriptions taken in conjunction with the accompanying drawings, in which:

FIG. 1 is a block diagram of an implementation computing system using a field programmable architecture with integrated analog in-memory computing cores;

FIG. 2 is a schematic of an implementation memristor Dot Product Engine (DPE) circuit that performs matrix multiplication operations within an FPGA;

FIG. 3 is a simplified layout of an implementation DPE region, which may be implemented in an FPGA in a non-limiting island-style layout;

FIG. 4 is a block diagram of an implementation DPE processing circuit, which may be implemented in each DPE core within an FPGA;

FIG. 5 shows various intra-layer pipeline implementations for the DPE processing circuit of FIG. 4 as implemented in an FPGA;

FIG. 6 is a pipelined execution timeline implemented by DPE cores within an FPGA;

FIG. 7 is a flowchart of an implementation method for converting pipeline stages from a high-level neural network model to hardware description language; and

FIG. 8 is a block diagram of an implementation conversion, showing how layers of a neural network model are converted to hardware implementations.

### DESCRIPTION

The following disclosure provides many different examples for implementing different features. Specific examples of components and arrangements are described below to simplify the present disclosure. These are, of course, merely examples and are not intended to be limiting.

The particular implementations are merely illustrative of specific configurations and do not limit the scope of the claimed implementations. Features from different implementations may be combined to form further examples unless noted otherwise. Various implementations are illustrated in the accompanying drawing figures, where identical components and elements are identified by the same reference number, and repetitive descriptions are omitted for brevity.

Variations or modifications described in one of the implementations may also apply to others. Further, various changes, substitutions, and alterations can be made herein without departing from the spirit and scope of this disclosure as defined by the appended claims.

While the aspects described primarily relate to neural network acceleration using analog dot product engines in field programmable gate arrays, these aspects may also apply to other computational systems and architectures. In particular, aspects of the disclosure may similarly apply to signal processing applications, scientific computing platforms performing linear algebra operations, optimization algorithms requiring repeated matrix operations, and hardware accelerators for machine learning inference. The techniques for integrating analog computation elements within reconfigurable digital circuits, managing analog-digital interfaces, and coordinating parallel processing flows may extend to other hardware platforms.

In implementations, a field programmable gate array architecture incorporates analog dot product engine (DPE) cores alongside configurable logic circuits to accelerate matrix computations while maintaining programmability. The DPE cores include arrays of programmable resistive memory elements that store matrix weights as resistance values and perform matrix-vector multiplications directly in the analog domain. An interconnect network couples the DPE cores with memory arrays and configurable logic circuits, enabling efficient data flow throughout the system.

In implementations, the architecture includes control circuitry that coordinates operations between analog and digital components. Input values may be converted to voltages and applied across rows of resistive elements, generating output currents representing computation results. The control circuitry manages the timing of these operations, data movement between components, and analog-digital signal conversion. Multiple DPE cores may operate in parallel, combining their results through digital accumulation circuits (e.g., shift and add (S&A) circuitry) that perform, for example, scaling and accumulation operations on the computation results.

A compilation process translates high-level neural network specifications into hardware descriptions utilizing hybrid analog-digital architecture. The process identifies matrix multiplication operations within network layers and maps them to appropriate DPE cores. Additional operations, such as activation functions and pooling, may be implemented using configurable logic circuits. The compilation generates control signals to coordinate data flow and pipeline operations across multiple network layers.

The architecture can support various neural network topologies through flexible mapping of operations to analog and digital components. Matrix operations may be partitioned across multiple DPE cores to optimize utilization and throughput. The control circuitry implements pipeline configurations based on layer dependencies and data flow requirements. Memory access patterns can be optimized to reduce data movement between storage and computation elements. These and additional details are further discussed below.

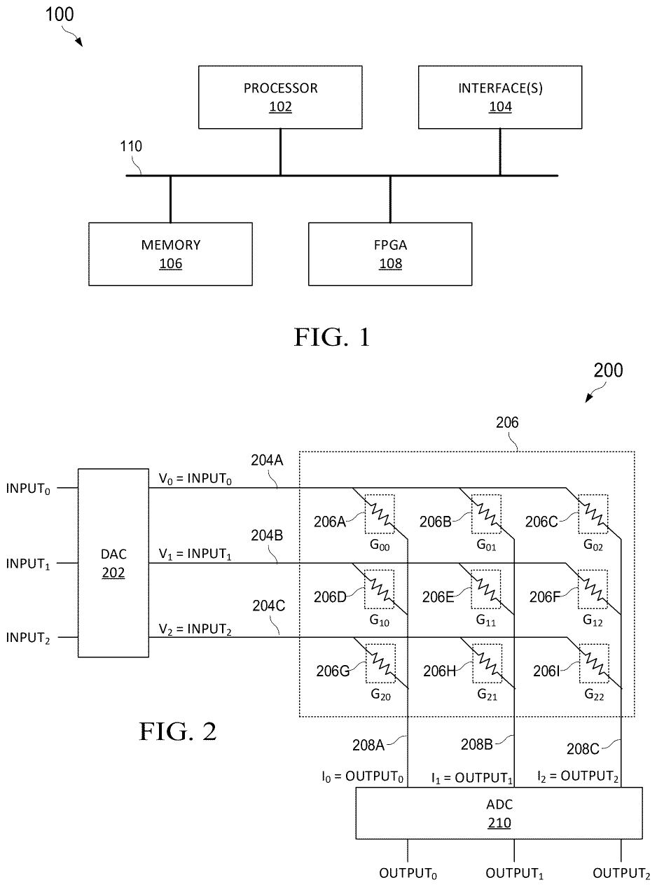

FIG. 1 illustrates a block diagram of an implementation computing system 100 using a field programmable architecture with integrated analog in-memory computing (e.g., DPE) cores. Computing system 100 includes a processor 102, one or more interfaces 104, memory 106, and a field programmable gate array (FPGA) 108. In an implementation, the components are coupled through a bus 110, which enables communication between the components. The computing system 100 may include additional components not shown in the figure, such as power management and supply circuitry and the like.

Although FIG. 1 depicts the computing system 100 with a single processor 102, memory 106, and FPGA 108, the number of each component may vary across different implementations. Computing system 100 may include multiple processors working in parallel, additional memory arrays distributed across the system, and multiple FPGAs with integrated DPE cores to increase computational capacity. The configuration shown in FIG. 1 illustrates a simplified architecture. At the same time, additional processors, memory arrays, FPGAs, and interfaces may be incorporated to scale processing capabilities, increase storage capacity, or enhance system throughput based on specific application requirements.

The computing system 100 may be implemented across various electronic devices, including servers, desktop computers, laptop computers, personal digital assistants (PDAs), mobile devices, smartphones, gaming systems, and tablets, among other electronic devices.

The computing system 100 with integrated analog DPE cores may operate in various deployment scenarios, from standalone FPGA accelerator cards to distributed cloud computing environments. In standalone configurations, the FPGA 108 may function as a local neural network accelerator, performing matrix computations using its analog in-memory computing capabilities. When deployed in networked environments, the system may operate across public, private, or hybrid cloud infrastructures, enabling flexible scaling of computational resources.

The analog in-memory computing capabilities may be offered as a service through various cloud delivery models. As Software as a Service (SaaS), the system may provide neural network acceleration through high-level applications. Platform as a Service (PaaS) implementations may expose the FPGA architecture with integrated DPE cores alongside operating systems and storage resources. Infrastructure as a Service (laaS) deployments may provide direct access to the hardware acceleration capabilities, including the analog computing cores, storage components, and networking resources. The system may also offer its matrix computation capabilities through an Application Programming Interface as a Service (APlaaS).

The FPGA-based acceleration system may span multiple hardware platforms, with analog computation tasks distributed across various DPE cores. This distributed architecture can be configured to support cloud-based and edge computing deployments, allowing matrix operations to be executed where appropriate based on data locality and performance requirements. In local deployment scenarios, a system administrator may directly manage the FPGA configuration and DPE core utilization through the one or more interfaces 104.

Processor 102 includes hardware architecture to retrieve and execute code from memory 106 that controls the operation of the analog DPE cores within FPGA 108. When executed, this code causes the processor 102 to coordinate programming and computation operations across the resistive memory arrays. For programming operations, processor 102 can apply first voltages to row lines within the DPE cores to configure resistive values of memristors located at crosspoint junctions. These programmed resistance values represent the weights of a matrix to be used in subsequent computations. During computation operations, processor 102 can apply second voltages to the row lines, where these voltages represent input vector values. Processor 102 can collect output currents from the column lines, with these currents representing the results of matrix-vector multiplication performed in the analog domain. Throughout these operations, the processor 102 coordinates with other system components through bus 110, managing data flow between memory 106, the FPGA 108, and interfaces 104.

In implementations, memory 106 stores executable code that controls the operation of the integrated analog DPE cores within FPGA 108 directly or through processor 102. This can include programming sequences for configuring resistive memory elements, control algorithms for managing analog computations, and routines for coordinating data flow between digital and analog domains. In an implementation, processor 102 retrieves and executes this code to implement the matrix multiplication acceleration capabilities of the system, including configuration of the DPE cores, management of input/output operations, and coordination of parallel processing across multiple analog computing arrays.

Memory 106 can incorporate various types of storage technologies to support different aspects of the FPGA-based analog computing system. This can include Random Access Memory (RAM) for active matrix data and computation results, Read Only Memory (ROM) for system initialization and DPE core configuration sequences, Hard Disk Drive (HDD) storage for large neural network models and accumulated computation results, or a combination thereof.

The system may utilize additional memory types for specific analog computing applications. During operation, processor 102 may boot configuration data for the DPE cores within the FPGA 108 from ROM, maintain neural network parameters and weight matrices in nonvolatile HDD storage, and use RAM to temporarily store input vectors and computation results.

Memory 106 may be implemented using various computer-readable storage media types capable of storing instructions and data for configuring and operating the FPGA-based analog computing system. These storage media may include electronic, magnetic, optical, electromagnetic, infrared, or semiconductor-based storage systems or combinations thereof. Specific implementations may utilize various storage technologies such as electrical connections with multiple wires, portable computer diskettes, hard disks, RAM, ROM, Erasable Programmable Read-Only Memory (EPROM), flash memory, portable Compact Disc Read-Only Memory (CD-ROM), optical storage devices, or magnetic storage devices. The storage media may be any tangible, non-transitory medium capable of storing computer-executable code, configuring the DPE cores, and managing their operation within the FPGA architecture.

The interfaces 104 enable processor 102 to communicate with the computing system's various internal and external hardware components. These interfaces connect input/output devices such as displays, mice, and keyboards for user interaction with the FPGA-based system. The interfaces 104 can also support connections to external storage devices and network equipment, including servers, switches, routers, and other computing devices that may utilize the analog matrix computation capabilities. This connectivity allows the integrated DPE cores to accelerate computations for local and networked applications, with results accessible to various client devices and computing systems.

The interface 104 can include display capabilities that enable users to interact with and control the FPGA-based analog computing system. Users may configure the DPE cores through these display interfaces, monitor matrix computations, and view processing results. Interface 104 can also support connections to output devices such as printers for recording computation results and network interfaces for transmitting matrix operation results to other computing devices across a network. This network connectivity enables the computing capabilities to be accessed and utilized by distributed applications and systems.

Through interface 104, the computing system 100 can provide Graphical User Interfaces (GUIs) to control and monitor analog computing capabilities. These GUls can enable users to input matrix and vector values for processing by the DPE cores within FPGA 108, configure the programmable resistive elements, and visualize computation results. Users may interact with the system through various display types supported by interfaces 104, including computer screens, laptop displays, mobile device screens, Personal Digital Assistant (PDA) displays, and tablet screens. The interactive interface allows users to program the resistive memory elements, initiate matrix-vector multiplications, and retrieve computation results through intuitive gestures and commands.

The FPGA 108 includes integrated DPE cores that perform matrix-vector multiplications using arrays of programmable resistive memory elements. In implementations, control circuitry within FPGA 108 can receive input values that define matrices to be used in computations and convert these values into programming signals for configuring the resistive elements of the DPE cores.

During operation, the control circuitry can apply input vectors to the programmed resistive arrays and collect output currents representing computation results. These analog computation results may be converted to digital values and transmitted to additional DPE cores or layers of the neural network model, processor 102, or other system components for further processing. The integrated DPE cores enable efficient matrix operations by performing computations directly in the analog domain, where weight values are stored as programmed resistances.

Accordingly, in various implementations, DPE cores are integrated within the computational circuits of FPGA 108 to enable in-memory computing using analog computation elements. Existing FPGA architectures include on-chip memory components for storing computation data and digital logic circuits for performing calculations. These digital components require multiple cycles to perform matrix operations and involve frequent data movement between memory and computation units.

Further, existing FPGA architectures faces performance limitations due to memory bottlenecks. Data is repeatedly transferred between storage elements and computation circuits, resulting in substantial overhead for read and write operations. This continuous data movement between memory and processing elements consumes significant time and energy.

Integrating DPE cores within FPGA 108 addresses these limitations by enabling matrix computations directly within memory elements. The enhanced FPGA architecture reduces data movement and improves computational latency and energy efficiency by performing calculations in the analog domain where data is stored. The DPE cores enable efficient acceleration of matrix operations while maintaining the reconfigurable benefits of the FPGA platform.

The FPGA 108 provides significant benefits through its reconfigurable architecture enhanced with analog DPE cores. The programmable nature of FPGA 108 enables customization for specific computational tasks, allowing the digital logic and analog computing resources to be optimized for particular matrix operations and neural network configurations. This flexibility, combined with the efficiency of in-memory computing through the employment of one or more DPE cores within the FPGA 108, results in improved power efficiency compared to general-purpose processors, making it particularly suitable for AI applications and edge computing scenarios where energy constraints may be significant.

The architecture of FPGA 108 can be tailored to specific workloads and algorithms, providing optimized performance for matrix computations by utilizing the parallel processing capabilities of multiple DPE cores alongside configurable digital logic, offering advantages in scenarios where Graphics Processing Units (GPUs) may operate less efficiently.

FIG. 2 illustrates a schematic of an implementation memristor Dot Product Engine (DPE) circuit 200 that performs matrix multiplication operations within FPGA 108. The DPE circuit 200 includes a Digital-to-Analog Converter (DAC) 202, a network of programmable resistive elements 206 arranged in a crossbar configuration, and an Analog-to-Digital Converter (ADC) 210, which may (or may not be arranged as shown). The DPE circuit 200 accelerates matrix computations through memristor crossbar arrays that accelerate computations by programming them with stable analog values and performing matrix operations directly in-memory.

In implementations, DPE circuit 200, as implemented within FPGA 108, enables matrix-vector multiplication by encoding matrix values as programmable conductances within memristor elements 206A-I arranged in a crossbar configuration. This analog in-memory computing approach allows matrix operations, which form central computations in neural networks and other processing-intensive workloads, to be executed directly in the analog domain where the weight values are stored. By programming specific conductance values into the memristor elements 206A-I and applying input voltages representing vector elements, the DPE circuit 200 performs multiplication and accumulation operations through the natural behavior of the resistive network, enabling efficient acceleration of neural network computations within the FPGA 108 architecture.

An input vector (INPUT) to the DPE circuit 200 includes three elements: a first input (INPUT₀), a second input (INPUT₁), and a third input (INPUT₃). Each element of the input vector (INPUT) represents digital values to be multiplied with a weight matrix (W) by the DPE circuit 200.

The digital input vector (INPUT) elements are provided to DAC 202, which converts them to corresponding analog voltages: a first analog voltage (V₀), a second analog voltage (V₁), and a third analog voltage (V₂); each forwarded to a corresponding row of the network of programmable resistive elements 206.

The network of programmable resistive elements 206 comprises 3 rows of electrodes 204A-C and 3 columns of electrodes 208A-C. At each crossbar junction where row and column electrodes intersect, a memristor element 206A-I is positioned. When the first analog voltage (V₀), the second analog voltage (V₁), and the third analog voltage (V₂) are applied to row electrodes 204A-C, a first current (I₀), a second current (I₁), and a third current (I₂) flow through the corresponding column electrodes 208A-C. These currents are provided to ADC 210, which converts them to digital values forming the output vector (OUTPUT): a first output (OUTPUT₀), a second output (OUTPUT₁), and a third output (OUTPUT₂), completing the vector-matrix multiplication operation. Accordingly, each element of the output vector represents a result of the vector-matrix multiplication operation.

In some implementations, sense circuitry (not shown) may be coupled to the column electrodes 208A-C to convert the output currents to voltages before analog-to-digital conversion.

It should be appreciated that although FIG. 2 depicts a 3×3 array of resistive elements 206A-2061, this configuration is non-limiting. Other implementations may include fewer or greater numbers of elements arranged in different array dimensions based on the size of matrices being processed. The array size may scale to accommodate larger matrix operations or be reduced for smaller computation requirements based on the size of the input and output vectors.

Further, each resistive element 206A-2061 shown in the simplified schematic may be coupled to additional components not explicitly illustrated. For example, each crosspoint may include a transistor coupled to the resistive element to control current flow, reduce sneak path currents through unselected elements, and enable more precise programming of conductance values. These additional circuit elements can enhance the accuracy and reliability of the analog matrix computations while maintaining the fundamental vector-matrix multiplication functionality illustrated in the figure.

The VMM operation of the DPE circuit 200 can be represented as:

$$[ \begin{matrix}\begin{matrix}{INPUT}_{0} & {INPUT}_{1}\end{matrix} & {INPUT}_{2}\end{matrix} ] \cdot [ \begin{matrix}{W}_{00} & {W}_{01} & {W}_{02} \\ {W}_{10} & {W}_{11} & {W}_{12} \\ {W}_{20} & {W}_{21} & {W}_{22}\end{matrix} ] = [ \begin{matrix}{OUTPUT}_{0} \\ {OUTPUT}_{1} \\ {OUTPUT}_{2}\end{matrix} ] ,$$

where a weight matrix (W) includes nine elements arranged in a 3×3 matrix configuration.

Each element of the weight matrix (W) represents a multiplication factor and is represented by a conductance value (G₀₀-G₂₂) that can be programmed into the memristor element 206A-I. Each memristor element 206A-I may be programmed to a specific conductance value corresponding to its respective matrix weight.

Accordingly, when the first analog voltage (V₀), the second analog voltage (V₁), and the third analog voltage (V₂) are applied to row electrodes 204A-C, the first current (I₀), the second current (I₁), and the third current (I₂) flowing through the column electrodes 208A-C represent the analog computation results, with each current being the sum of products between input voltages and corresponding conductance values in that column.

An example implementation of the DPE circuit 200 is illustrated in U.S. Pat. No. 10,262,733 B2, which is incorporated herein by reference in its entirety.

In implementations, the FPGA 108 can integrate analog in-memory computing capabilities through DPE cores based on non-volatile Resistive Random Access Memory (ReRAM) devices. These DPE cores, exemplified by DPE circuit 200, incorporate arrays of programmable memristor elements 206A-I that store matrix weights as conductance values while performing computations in the analog domain.

Integrating DPE cores within FPGA 108 enhances the digital fabric with analog computing capabilities, enabling efficient matrix operations through in-memory computation. This hybrid architecture combines the flexibility of programmable digital logic with the efficiency of analog matrix multiplication, where computations occur directly within the memristor elements 206A-I storing the weight values.

While computing needs continue to increase, particularly for neural network applications, improvements in chip manufacturing have slowed. Within this context, FPGA 108 with integrated DPE cores provides a path forward by combining reconfigurable digital logic with efficient analog computing capabilities. The DPE circuit 200 addresses the memory bottleneck by performing matrix computations directly within the memristor elements 206A-I, eliminating the need to move data between separate memory and computation units repeatedly. This in-memory computing approach may significantly improve performance and energy efficiency compared to existing digital implementations.

Accordingly, integrating analog in-memory computing within FPGA 108 represents an advancement in reconfigurable hardware design. By combining the flexibility of FPGA architecture with the efficiency of analog computation through DPE circuits 200, this approach enables acceleration of modern AI workloads such as Convolutional Neural Networks (CNNs). The system may be deployed as dedicated hardware or accessed through cloud-based services, providing flexible implementation options for various applications and deployment scenarios.

In implementations, the DPE circuit 200 is integrated as computational macros within an enhanced FPGA architecture, such as FPGA 108. This integration requires the configuration of peripheral circuitry and input/output interfaces to ensure proper operation within the FPGA fabric. The peripheral circuitry manages data flow between the analog computation elements and digital components, while the input/output interfaces coordinate signal timing and conversion between analog and digital domains.

The DPE circuit 200 is synchronized with other FPGA components to maintain efficient pipeline operation. This synchronization includes coordinating analog-to-digital conversions, managing data transfer timing, and aligning computation cycles with memory access patterns. The alignment of DPE operations with digital logic ensures proper data flow through the processing pipeline while maintaining the accuracy of analog computations.

Integrating DPE cores within FPGA 108 necessitates modifications to existing FPGA synthesis processes. Commercial FPGAs typically support basic arithmetic operations such as addition and multiplication, which can be implemented using, for example, lookup tables and standard digital logic. However, the synthesis tools for these FPGAs do not inherently support matrix-vector multiplication as a fundamental instruction.

Adding DPE cores introduces new capabilities that extend beyond existing FPGA operations. While the fundamental matrix-vector multiplication functionality remains unchanged, the synthesis flow adapts to accommodate these analog computation elements. The process considers how to map high-level matrix operations to the DPE cores, manage analog-digital interfaces, and coordinate data flow between memory elements and computational units.

These synthesis adaptations enable efficient utilization of the enhanced FPGA architecture. Rather than decomposing matrix operations into sequences of basic arithmetic instructions, the synthesis process can map these operations directly to DPE cores, taking advantage of their analog computing capabilities while maintaining the FPGA's reconfigurable nature.

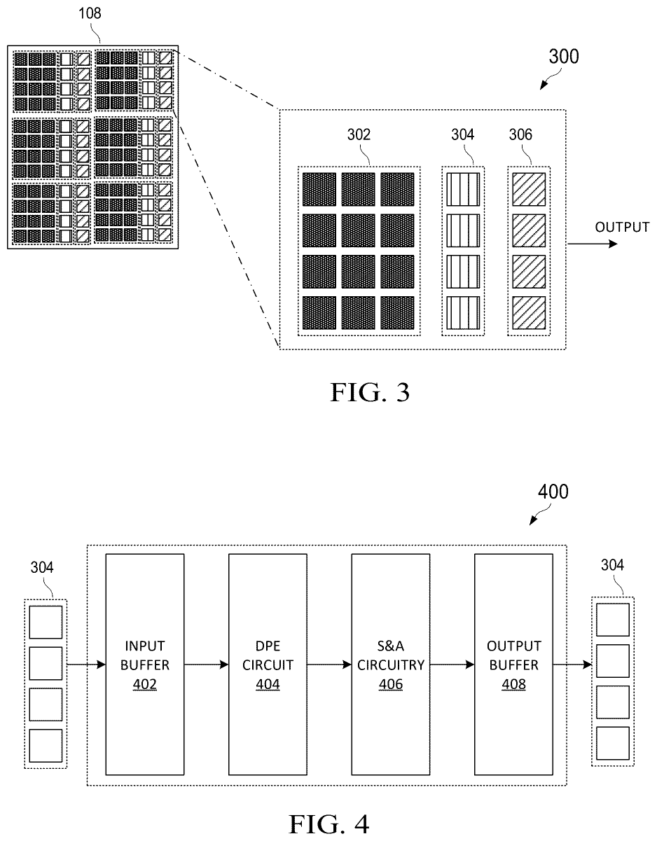

FIG. 3 illustrates a simplified layout of an implementation DPE region 300, which may be implemented in the FPGA 108 in a non-limiting island-style layout. In implementations, each DPE region 300 corresponds to a processing layer of a neural network. Each DPE region 300 includes DPE cores 302 for analog matrix computations, memory arrays 304 for data storage, and Look-Up Tables (LUTs) 306 for digital processing operations, which may (or may not) be arranged as shown.

DPE region 300 may include additional components not shown, such as control circuitry to coordinate operations between components by managing data flow and timing relationships. The control circuitry can implement pipeline stages by coordinating when each component processes data, ensuring proper sequencing of operations across the various stages of the pipeline. For matrix computations, control circuitry can manage the programming of resistive elements within DPE cores 302 and coordinate the conversion of data between analog and digital domains.

The DPE cores 302 perform matrix-vector multiplications in the analog domain, similar to the operation of DPE circuit 200 described in FIG. 2. Memory arrays 304 store input vectors, partial sums, and computation results, providing local storage to minimize data movement between processing stages. The LUTs 306 implement digital operations required by neural network processing, such as activation functions and pooling operations.

The DPE cores 302 are arranged in an array configuration, where each element represents an individual DPE circuit similar to DPE circuit 200. Memory arrays 304 include memory elements for storing data at different stages of computation. The LUTs 306 similarly include programmable logic elements that can be configured to implement various digital processing functions by the neural network layer. The LUTs 306 perform digital operations between matrix computations in neural network processing. These operations may include activation functions that introduce non-linearity into the network, pooling operations that reduce data dimensionality, or other digital transformations by the neural network architecture.

Although FIG. 3 shows specific numbers of DPE cores, memory elements, and LUTs, these quantities are for illustration purposes. Other implementations may include fewer or greater numbers of each component based on specific application requirements and desired computational capabilities.

Multiple DPE regions may be arranged within FPGA 108 to support neural networks with multiple layers, where each region processes a different layer of the network. The organization of DPE cores 302, memory arrays 304, and LUTs 306 within each region enables the pipelining of operations. The DPE region 300 generates a digital output vector (OUTPUT) that may represent either final results of the neural network computation or intermediate results to be processed by subsequent DPE regions implementing additional network layers.

The FPGA 108 includes input/output (I/O) interfaces, for example, around its perimeter to enable communication with external components. These I/O interfaces allow data transfer between the FPGA 108 and other system components, such as processor 102. Various communication protocols may be supported, such as Peripheral Component Interconnect Express (PCIe), enabling external devices to send computation requests to FPGA 108 and receive processed results. Through these interfaces, external components can provide input data to the DPE regions 300, initiate computations, and retrieve output results, facilitating integration of the analog computing capabilities within larger processing systems.

The placement and routing of DPE regions 300 within FPGA 108 may be optimized based on algorithmic requirements and physical constraints. As an example, DPE regions 300 positioned near the top or bottom of FPGA 108 can provide shorter paths to I/O interfaces, enabling more efficient data transfer with external components. The optimization process can avoid centrally located DPE regions 300 when possible, as these may require longer routing distances to reach I/O interfaces based on, for example, the FPGA layout. Based on the specific computational requirements and circuit implementation, optimization tools can determine the optimal placement and routing of components within FPGA 108, minimizing signal path lengths and maximizing performance.

For example, when implementing computations that require a single memory array 304 and DPE core 302, the optimization process may select regions closer to the I/O interfaces at the FPGA's perimeter. This placement can reduce signal path lengths and simplifies routing compared to utilizing DPE regions in the center of the FPGA fabric.

In implementations, control circuitry in each DPE region 300 is synthesized using LUTs 306 and memory arrays 304 (e.g., RAM) within the FPGA 108 fabric. Rather than existing as distinct physical blocks, the control logic can be distributed and implemented through configured LUTs near their corresponding DPE cores 302. This localized control approach can enable direct management of DPE operations without relying on external control signals from processor 102. The synthesized control circuitry can coordinate data movement between memory arrays 304 and DPE cores 302, manage programming sequences for the resistive elements, and maintain proper timing relationships for analog computations. By implementing control functions through configured LUTs near each DPE core 302, the architecture can minimize control signal routing distances and enable efficient coordination of local processing operations.

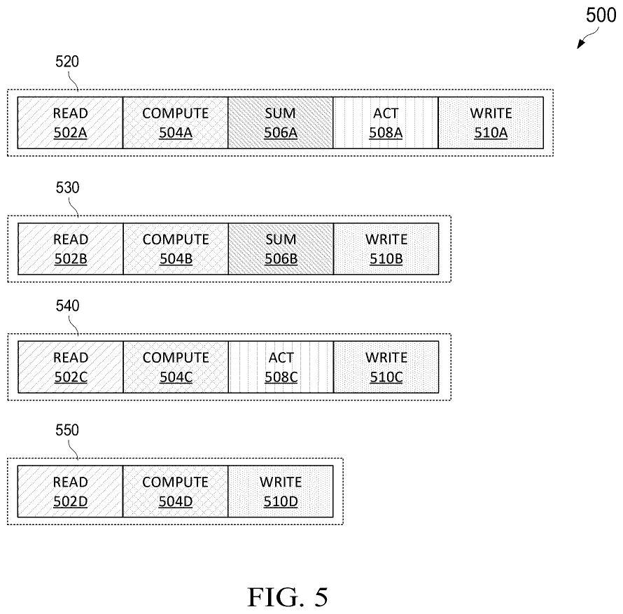

FIG. 4 illustrates a block diagram of an implementation DPE processing circuit 400, which may be implemented in each DPE core 302 within FPGA 108. The DPE processing circuit 400 includes an input buffer 402, a DPE circuit 404, Shift and Add (S&A) circuitry 406, and an output buffer 408 arranged in a processing pipeline, which may (or may not) be arranged as shown. DPE processing circuit 400 may include additional components not shown.

The DPE processing circuit 400 fetches the input vectors stored in the memory arrays 304. The input buffer 402 receives the digital input vectors and partial sum (PS) values from memory arrays 304. These values may represent either initial input data for the neural network layer or intermediate results from previous computations. The input buffer 402 temporarily stores these values and coordinates with the DPE circuit 404 to convert them into analog voltages suitable for DPE circuit 404, as previously discussed, for example, concerning the DPE circuit 200 of FIG. 2. The buffering enables continuous data flow by allowing new input values to be loaded while previous computations are still processing.

The DPE circuit 404 contains a crossbar array of mem-resistive elements that are programmed with weight values before performing computations. During an initialization phase, weight values corresponding to the neural network layer are converted to programming voltages that configure the conductance of each mem-resistive element. In implementations, the programming operations occur sequentially to ensure accurate weight storage, with verification steps possible between programming operations. Once programmed, the mem-resistive elements can maintain their conductance values through multiple computation cycles.

During computation, the analog voltages representing input vectors interact with the programmed weights in DPE circuit 404 to perform matrix multiplication through Ohm's law. The resulting output currents from each column represent partial products of the matrix multiplication. These currents may be processed by sense amplifiers to convert them to voltages before digitization by ADC 210. The S&A circuitry 406 performs necessary scaling and accumulation operations on the digitized results.

The S&A circuitry 406 enhances the precision of matrix computations by performing shift and add operations on the digitized results from ADC 210. While DPE circuit 404 performs matrix-vector multiplications using mem-resistive elements that may have limited precision, the S&A circuitry 406 enables higher precision computations through the digital combination of sliced inputs and weights. When input vectors or weight matrices are sliced to work within the precision limitations of the mem-resistive elements in DPE circuit 404, multiple partial products are scaled and combined. The S&A circuitry 406 performs bit shift operations on these digitized partial results and accumulates them to construct higher precision final results. For example, 8-bit precision computations may be achieved using 4-bit mem-resistive elements by appropriate slicing, shifting, and combining of partial results.

In some implementations, the output currents from DPE circuit 404 may be directly coupled to analog S&A circuitry that performs shift and add operations in the analog domain before conversion to digital values by ADC 210. This alternative arrangement may reduce power consumption and circuit complexity by performing scaling and accumulation operations while signals remain in the analog domain.

The output buffer 408 receives processed results from S&A circuitry 406 and coordinates their storage back to memory arrays 304. For intermediate layers of the neural network, these results may be provided to LUTs 306 for additional digital processing, such as activation functions or pooling operations, before becoming inputs for subsequent DPE processing circuits. The output buffer 408 can implement handshaking protocols with memory arrays 304 to ensure proper data transfer timing and prevent data loss during continuous operation.

In implementations, the DPE processing circuit 400 represents a computational element within each DPE core 302 of DPE region 300. Multiple DPE regions 300 may be arranged across the FPGA 108 fabric to implement different layers of a neural network, with each region's memory arrays 304, DPE cores 302, and LUTs 306 configured for that layer's specific computational requirements.

In such implementations, the output buffer 408 of a DPE processing circuit 400 in one DPE region 300 may feed its results through memory arrays 304 to the input buffer 402 of a DPE processing circuit 400 in a subsequent DPE region. This arrangement creates a processing pipeline across neural network layers, where each DPE region 300 processes its layer's computations while previous regions prepare new data and subsequent regions complete their operations. The LUTs 306 in each region perform necessary digital operations between layers, such as activation functions or pooling operations.

The scalable nature of this architecture allows FPGA 108 to be configured for neural networks of varying depths and complexities. Additional DPE regions may be instantiated within the FPGA 108 fabric to support deeper networks, with the interconnect network providing flexible routing between regions. For neural networks requiring additional computational resources beyond a single device, multiple FPGAs 108 may be coupled through their interfaces 104, allowing DPE operations to extend across multiple hardware platforms. This distributed processing capability enables scaling of neural network implementations beyond the resources available in a single FPGA 108.

The pipelined architecture of DPE processing circuit 400 enables overlapped execution of these operations, with input loading, matrix multiplication, and result storage occurring simultaneously on different data sets. Control signals coordinate the timing between stages to maintain data coherency and maximize throughput. This organization supports efficient processing of neural network layers by maintaining constant data flow through the analog computation stages while managing the necessary digital-to-analog and analog-to-digital conversions at the interfaces.

In implementations, DPE circuit 404 may be shared across multiple operations to optimize resource utilization and improve system efficiency. For example, when a layer's computational requirements do not fully utilize the DPE circuit's capacity, multiple layers or operations may share the same DPE circuit 404. If a layer requires 50% of the DPE circuit's computational elements, two similar layers may be mapped to the same DPE circuit 404 rather than instantiating separate, underutilized circuits. This resource sharing optimizes hardware utilization, improves system latency, and increases throughput performance while maintaining computational throughput.

Parting and sharing the DPE circuit 404 enables efficient mapping of neural network operations to available hardware resources. The control circuitry can manage the scheduling and coordination of shared DPE circuit access, ensuring proper execution timing and data management when multiple operations utilize the same computational resources. This optimization approach reduces hardware overhead while maximizing the utilization of analog computing capabilities within FPGA 108.

The integration of DPE cores within FPGA 108 influences the FPGA's architectural design while maintaining the fundamental operation of the dot product engine. The FPGA architecture adapts to accommodate analog computation elements alongside digital logic, affecting signal routing, clock distribution, and power delivery networks.

The interface requirements between DPE cores and surrounding circuits differ significantly when implemented within an FPGA compared to other platforms such as ASICs. These interfaces manage the transition between analog and digital domains, coordinate timing relationships, and handle data flow within the programmable fabric. The design of these interfaces considers the reconfigurable nature of FPGAs and their standardized communication protocols.

Adapting DPE cores for FPGA implementation primarily affects the peripheral circuitry and communication mechanisms rather than the core analog computation elements. This approach preserves the efficiency benefits of analog matrix multiplication while enabling integration within a reconfigurable digital platform.

Thus, integrating DPE cores 302 within FPGA 108 requires consideration of the FPGA fabric's specific requirements and constraints. Generally, the DPE cores cannot be implemented in an FPGA-agnostic manner, as data transfer mechanisms to and from the DPE cores are to align with the FPGA's communication grid. This communication infrastructure can differ significantly from implementations in custom application-specific integrated circuits (ASICs) or dedicated non-volatile memory crossbar arrays, necessitating adaptations for FPGA integration.

The instruction flow accounts for the cores' embedded position within the FPGA fabric when implementing computation sequences using the DPE cores 302 within the DPE processing circuit 400 as implemented in the FPGA 108. The compilation process considers FPGA-specific requirements such as timing constraints and memory access limitations. These considerations affect how data is fed to and fetched from the DPE cores, influencing the physical design and operational parameters.

Accordingly, the design of the FPGA architecture and the DPE cores exhibits a codependent relationship. The FPGA's communication infrastructure, memory organization, and timing requirements influence the DPE core design, while the DPE cores' analog computation capabilities and data flow requirements shape the FPGA's architectural features. This interdependence ensures efficient integration and operation of analog computing capabilities within the digital FPGA fabric.

FIG. 5 illustrates various intra-layer pipeline implementations 500 for the DPE processing circuit 400 as implemented in an FPGA 108. When implementing neural network models in FPGA 108, it is advantageous for the architecture to employ parallelization and pipelining to maximize computational efficiency. This approach can follow a data flow paradigm where information moves from input to output through multiple concurrent processing paths, enabling parallel operations while maintaining pipelined execution.

The data flow structure enables collective movement of data through the processing stages in a parallel and pipelined manner, minimizing latency and maximizing throughput. This organization considers the execution time of different instructions and operations, allowing optimal scheduling and overlap of computations. Each layer may include multiple distinct operations: READ, COMPUTE, SUM, ACT, and WRITE. The specific sequence and number of stages vary depending on whether the layer performs convolutional operations using DPE cores 302 or pooling operations using LUTs 306.

Convolutional layers perform matrix-vector multiplications using DPE cores 302, requiring either the full five-stage pipeline (i.e., the first pipeline implementation 520) (with activation functions) or four-stage pipeline (i.e., the second pipeline implementation 530) (without activation functions) when using multiple DPE cores 302. For single DPE core implementations, convolutional layers use either four stages (e.g., the third pipeline implementation 540) (with activation functions) or three stages (e.g., the fourth pipeline implementation 550) (without activation functions).

Pooling layers, which perform operations like maximum or average value selection over regions of input data, use the simplified three-stage pipeline (e.g., the fourth pipeline implementation 550). Unlike convolutional layers that require analog matrix multiplication in DPE cores 302, pooling operations are implemented directly in digital logic using LUTs 306, eliminating the need for SUM and ACT stages.

A first pipeline implementation 520 includes five intra-layer stages for processing layers with multiple DPE cores 302 and activation functions: a READ stage 502A, a COMPUTE stage 504A, a SUM stage 506A, an ACT stage 508A, and a WRITE stage 510A.

A second pipeline implementation 530 includes four intra-layer stages for layers with multiple DPE cores 302 without activation functions: a READ stage 502B, a COMPUTE stage 504B, a SUM stage 506B, and a WRITE stage 510B.

A third pipeline implementation 540 depicts four intra-layer stages for single DPE core implementations with activation functions: a READ stage 502C, a COMPUTE stage 504C, an ACT stage 508C, and a WRITE stage 510C.

A fourth pipeline implementation 550 shows three intra-layer stages for (1) single DPE core implementations without activation functions or (2) pooling layers: a READ stage 502D, a COMPUTE stage 504D, and a WRITE stage 510D. COMPUTE stage 504D implements pooling operations rather than matrix multiplication for pooling layers.

The READ stage (502A-D) reads input data from memory arrays 304 into input buffer 402. This includes reading input vectors and partial sums for matrix multiplication operations for convolutional and linear layers. For pooling layers, this involves reading feature map data to be pooled.

The COMPUTE stage (504A-D) performs the core mathematical operations. DPE circuit 404 executes matrix-vector multiplications in the analog domain using programmed conductance values in the mem-resistive elements for convolutional and linear layers. For pooling layers, this stage performs operations such as maximum or average calculations over specified regions of the input data.

The SUM stage (506A-B), present in multi-DPE implementations, accumulates partial results from multiple DPE circuits 404 through, for example, S&A circuitry 406. This stage combines results when matrix operations are partitioned across multiple DPE cores 302, ensuring all partial products are properly accumulated into final results.

The ACT stage (508A, 508C) implements activation functions using LUTs 306. Common activation functions include Rectified Linear Unit (ReLU), sigmoid, or hyperbolic tangent (tanh), which introduce non-linearity into the neural network computations. This stage processes the accumulated results from previous stages through the specified activation function.

The WRITE stage (510A-D) stores processed results from output buffer 408 back to memory arrays 304. For intermediate layers, these results become inputs for subsequent layer computations. For the final layer, these results represent the neural network's output.

The specific intra-layer pipeline implementation can depend on the neural network layer type and computational requirements. Some stages may be omitted if their corresponding computation is not needed in a particular layer implementation.

The implementation of these pipeline stages represents a new approach to FPGA computation, as no established framework exists for compiling operations for DPE cores within an FPGA fabric. Existing FPGA instruction sets and compilation methods do not account for analog matrix computation elements or their integration with digital logic. The pipeline implementations 500, therefore, define new instruction sequences and timing relationships specific to the hybrid analog-digital architecture of FPGA 108.

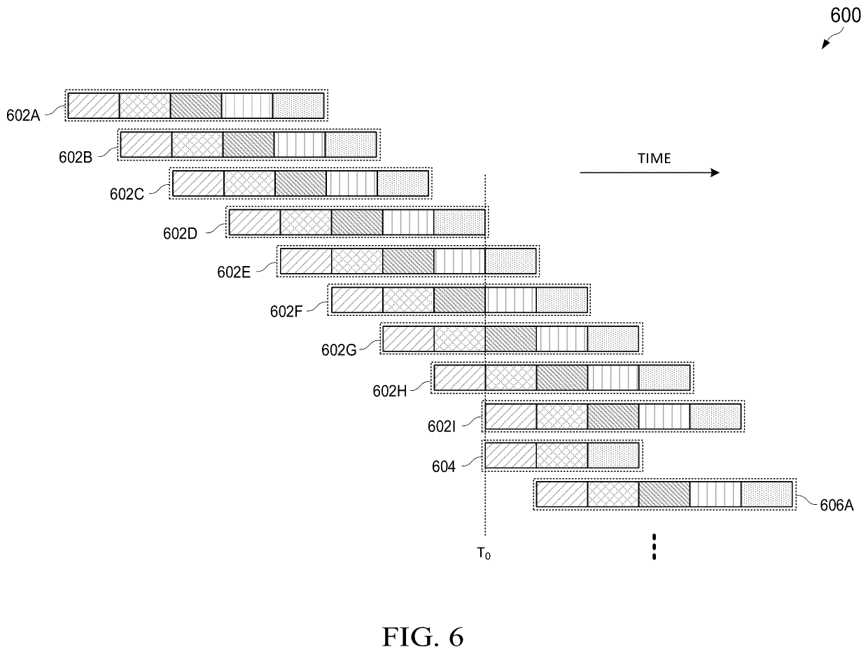

FIG. 6 illustrates a pipelined execution timeline 600 implemented by a DPE cores 302 within FPGA 108. The pipelined execution timeline 600 shows, for example, how a convolutional layer and a pooling layer process data across time. The timeline demonstrates how the FPGA 108 achieves throughput through an overlapped execution model. Rather than waiting for the convolutional layer to complete all its outputs, the pooling layer begins processing at time T₀ when sufficient input data becomes available, maximizing hardware utilization and minimizing processing latency.

In neural networks, the convolutional layer generally performs filtering operations by applying a matrix of weights (filter or kernel) to input vectors to produce output vectors. The input vectors are typically represented as N×N arrays of values, where N defines the width and height of the square array. The weight matrix is an M×M array that determines how input values are combined through matrix-vector multiplication operations performed by DPE cores 302. The stride size determines how many positions the weight matrix moves between computations-a stride of 1 means the matrix moves one position at a time, while a stride of 2 means it skips every other position.

A pooling layer reduces the spatial dimensions of its input vectors by summarizing values within fixed-size windows. Like the convolutional layer, it slides a window (e.g., 2×2) across its input vectors using a specified stride size. The pooling operation may compute the maximum, average, or other statistical function of the values within each window position, producing smaller output vectors.

In the example shown in FIG. 6, a convolutional layer is followed by a pooling layer. Here, it is assumed that the convolutional layer receives a 4×4 input vector and applies a 2×2 weight matrix with a stride size of 1, producing a 3×3 output vector. The 3×3 output vector from the convolutional layer serves as input to the pooling layer, which applies a 2×2 pooling window with a stride size of 1 to produce a 2×2 output vector.

Pipeline sequences 602A-602I represent nine consecutive processing cycles of the same convolutional layer, where each sequence includes the five pipeline stages (READ, COMPUTE, SUM, ACT, WRITE) described in the first pipeline implementation 520 of FIG. 5. In each cycle, the convolutional layer produces one new output value for its 3×3 output vector through matrix-vector multiplication operations in the DPE cores 302.

At time T₀, after the fourth processing cycle (sequence 602D), the convolutional layer has generated enough outputs to provide the first 2×2 window of input data for the pooling layer. At this point, pipeline sequence 604 begins the pooling layer operation. The pooling layer applies its 2×2 window with a stride size of 1 to the available outputs, using the three pipeline stages (READ, COMPUTE, WRITE) shown in the fourth pipeline implementation 550 of FIG. 5.

Additional pipeline sequences 606A and subsequent sequences continue this operation pattern after time T₀. This pipelined architecture enables efficient processing by allowing new computations to begin as soon as their required inputs become available, maximizing hardware utilization and minimizing processing latency. For example, while the convolutional layer continues producing outputs through sequences 602E-602I, the pooling layer can simultaneously process the already-available outputs from earlier cycles.

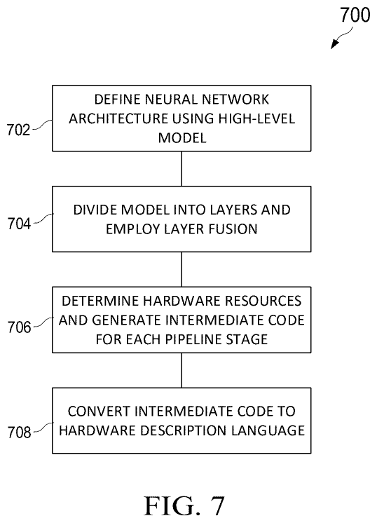

FIG. 7 illustrates a flowchart of an implementation method 700 for converting pipeline stages from a high-level neural network model to hardware description language.

Currently available model-to-hardware conversion tools are designed for purely digital implementations and cannot adequately handle the specialized requirements of analog DPE cores within an FPGA fabric, as disclosed herein. These requirements include, for example, managing analog-to-digital and digital-to-analog conversions, coordinating data flow between memory arrays and analog computation elements, controlling programming sequences for mem-resistive elements, and implementing precise timing for analog operations.

The design of FPGA 108 and its compilation process are fundamentally intertwined through multiple phases of implementation. While optimization represents one aspect of this relationship, the integration of DPE cores affects all phases of the synthesis process. The compilation and synthesis considerations for DPE cores extend beyond digital logic circuits typically integrated into FPGAs.

The synthesis phase accounts for the unique requirements of analog computation elements within the digital fabric. This includes managing analog-digital interfaces, coordinating timing between analog and digital operations, and ensuring proper routing of signals to and from the DPE cores. These considerations influence the physical design of FPGA 108 and the compilation tools that generate its hardware description, creating an integrated relationship between architecture and implementation methodology.

Method 700 addresses these challenges through a custom implementation flow that enables efficient exploration of FPGA design space and profiling of implementations with integrated in-memory computing cores.

At step 702, the method starts with a high-level model specification that defines a neural network architecture. The model may be defined using various programming languages and frameworks. In some implementations, Python is used to define the model. In some implementations, the Python model may be created using the PyTorch framework. The model specifies the sequence of computational layers, their configurations, and trained parameters, including specifications for convolutional layers (with filter sizes, stride values, and weight matrices), pooling layers (with window sizes and stride values), activation functions, and batch normalization parameters.

At step 704, the model is divided into multiple layers and layer fusion is employed. For example, each layer may include a convolutional operation with batch normalization, activation functions, or pooling operation. When batch normalization or activation functions follow a convolutional layer, these operations are fused into a single layer, with batch normalization parameters incorporated into the convolutional weights and bias values.

At step 706, the requisite hardware resource allocation is determined, and intermediate code for each pipeline stage is generated. For convolutional layers, this can include, for example, mapping input size to input Static Random Access Memory (SRAM) size, filter size and stride size to number of desired DPE cores, and output size to output SRAM size. For pooling layers, this can include, for example, mapping input size to input SRAM size, pooling window size to number of required pooling operations, and output size to output SRAM size.

Further, the specific code implementations for each pipeline stage within each layer are generated. In some implementations, this code may be written in Python. For example, for layers using multiple DPE cores 302, the code can include summation operations to accumulate results from multiple DPE cores. As another example, for layers with activation functions, the code can include computation of the activation operations.

In implementations, each processing element includes a lightweight controller to manage communication between neighboring layer blocks and control write/read operations.

At step 708, the intermediate code is converted into hardware description language. Various hardware description languages may be used. In some implementations, Verilog may be used as the hardware description language. The conversion from intermediate code to hardware description language may be performed using various tools. In some implementations, PyLog and the VTR (Verilog-to-Routing) framework may be used. The resulting hardware description implements the pipeline stages described in FIGS. 5 and 6, enabling efficient processing of neural network operations in hardware while maintaining the flexibility to explore different FPGA architectural configurations.

It is noted that all steps outlined in the method are not necessarily required and can be optional. Further, changes to the arrangement of the steps, removal of one or more steps and path connections, and addition of steps and path connections are similarly contemplated.

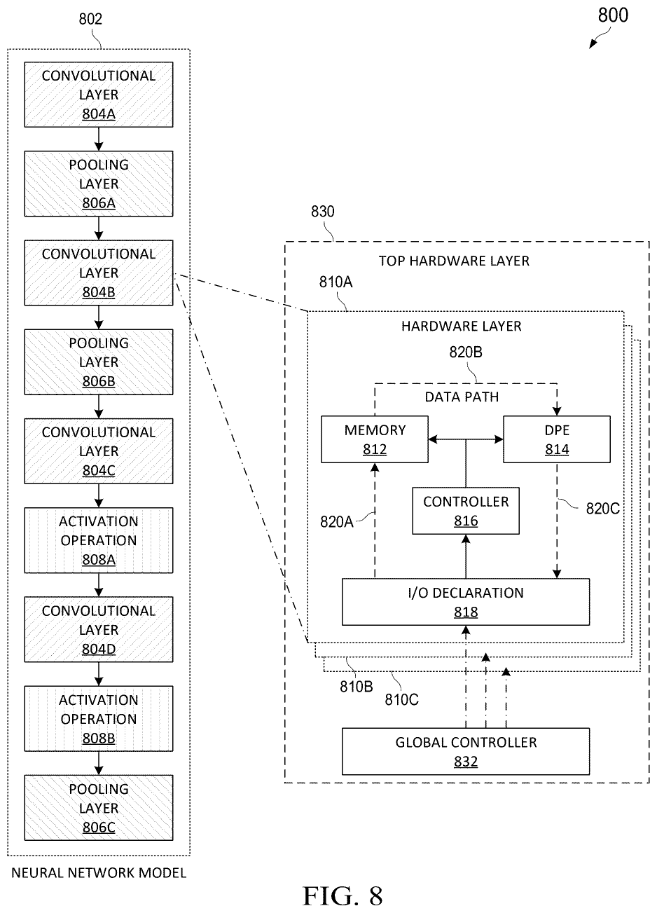

FIG. 8 illustrates a block diagram of an implementation conversion 800, showing how layers of a neural network model 802 are converted to hardware implementations. The neural network model 802 includes a sequence of computational layers including convolutional layers 804A-D, pooling layers 806A-C, and activation operations 808A-B arranged in a processing pipeline, which may (or may not) be arranged as shown. The neural network model 802 may include additional layers not shown.

Hardware layer 810A illustrates an example of the conversion of convolutional layer 804B into a hardware implementation using, for example, method 700 described in FIG. 7. Similar conversions may be performed for other layers in the neural network model 802 using method 700. The hardware layer 810A includes memory 812 for storing input and output data, a DPE 814 for performing matrix computations, and a controller 816 that manages data flow and timing. These components are coupled through data paths 820A-C and communicate through an I/O declaration interface 818.

The memory 812 stores input vectors, weight matrices, and computation results. The DPE 814 performs matrix-vector multiplication operations for convolutional layers 804A-D using analog in-memory computing as described concerning FIGS. 2-4. The controller 816 coordinates operations between memory 812 and DPE 814, managing the pipeline stages described in FIGS. 5-6. The I/O declaration interface 818 defines the communication protocols between components and neighboring layers.

The modular organization enables the mapping of neural network operations to the FPGA 108 architecture, with each hardware layer 810 containing the control logic and memory management for its specific layer type. Multiple hardware layers may be instantiated and connected to implement the neural network model 802.

The top hardware layer 830 includes multiple hardware layers 810A-C that implement different portions of the neural network model 802. In implementations, each hardware layer 810A-C contains similar components (e.g., memory 812, DPE 814, controller 816, and I/O declaration interface 818), but can be configured differently based on their corresponding neural network layer requirements. The hardware layers 810A-C are coupled to a global controller 832 through their respective I/O declaration interfaces 818, enabling data flow between the top hardware layer 830 and each hardware layer 810.

The global controller 832 coordinates operations across the hardware layers 810A-C through connections to their I/O declaration interfaces 818. The global controller 832 manages the overall execution sequence, synchronizes data transfers between layers, and ensures proper pipeline timing across the entire neural network implementation. Through these connections, the global controller 832 can initiate operations in each hardware layer, monitor their status, and coordinate the data flow.

For example, when hardware layer 810A completes processing its data, the global controller 832 can signal hardware layer 810B to begin its operations using the results from 810A. The global controller 832 can also manage resource allocation and scheduling when multiple neural network layers share hardware resources.

Although FIG. 8 depicts a specific arrangement and number of layers, this configuration is non-limiting and shown for illustration purposes. In other implementations, the neural network model 802 may include fewer or greater numbers of layers, different types of layers, and various arrangements of layers based on specific neural network architectures and application requirements.

Although this disclosure describes or illustrates particular operations as occurring in a particular order, this disclosure contemplates the operations occurring in any suitable order. Moreover, this disclosure contemplates any suitable operations being repeated one or more times in any suitable order. Although this disclosure describes or illustrates particular operations as occurring in sequence, this disclosure contemplates any suitable operations occurring at substantially the same time, where appropriate. Where appropriate, any suitable operation or sequence described or illustrated herein may be interrupted, suspended, or otherwise controlled by another process, such as an operating system or kernel. The acts can operate in an operating system environment or as stand-alone routines occupying all or a substantial part of the system processing.

While this disclosure has been described with reference to illustrative implementations, this description is not intended to be construed in a limiting sense. Various modifications and combinations of the illustrative implementations, as well as other implementations of the disclosure, will be apparent to persons skilled in the art upon reference to the description. Therefore, the appended claims are intended to encompass any such modifications or implementations.

What is claimed is:

1. A computer system comprising a field programmable gate array, the field programmable gate array comprising:
a configurable logic circuit;
an analog dot product engine (DPE) core integrated within the field programmable gate array, the DPE core comprising:
a digital-to-analog converter configured to convert digital input vectors to analog voltages,
an array of programmable resistive memory elements arranged in a crossbar configuration configured to store matrix weights and perform matrix-vector multiplication in an analog domain, and
an analog-to-digital converter configured to convert output currents from the array of programmable resistive memory elements to digital values;
a memory array coupled to the DPE core and configured to store the digital input vectors and the digital values; and
control circuitry configured to implement pipeline stages comprising read, compute, sum, activation, write operations, or combinations thereof, for coordinating data flow between the memory array, the DPE core, and the configurable logic circuit.

2. The computer system of claim 1, wherein the DPE core further comprises:
an input buffer coupled to the digital-to-analog converter and configured to temporarily store the digital input vectors; and
an output buffer coupled to the analog-to-digital converter and configured to temporarily store the digital values.

3. The computer system of claim 1, wherein the array of programmable resistive memory elements comprises:
a plurality of row lines;
a plurality of column lines; and
memristor elements positioned at crossbar junctions where the row lines and column lines intersect.

4. The computer system of claim 1, wherein the DPE core further comprises shift and add circuitry configured to:
perform bit shift operations on the digital values; and
accumulate the shifted digital values to construct higher precision results.

5. The computer system of claim 1, wherein the configurable logic circuit comprises look-up tables configured to:
implement activation functions between matrix computations; and
perform pooling operations for reducing data dimensionality.

6. The computer system of claim 1, wherein the control circuitry is further configured to:
apply first voltages to program resistance values of the programmable resistive memory elements; and
apply second voltages representing the digital input vectors to perform the matrix-vector multiplication.

7. The computer system of claim 1, wherein the pipeline stages are configured to:
read the digital input vectors from the memory array;
compute the matrix-vector multiplication using the DPE core;
sum partial results from the DPE core;
apply activation functions using the configurable logic circuit;
write the digital values to the memory array; or a combination thereof.

8. A field programmable gate array, comprising:
a configurable logic circuit;
an analog dot product engine (DPE) core comprising:
a digital-to-analog converter configured to convert digital input vectors to analog voltages,
an array of programmable resistive memory elements arranged in a crossbar configuration configured to store matrix weights and perform matrix-vector multiplication in an analog domain, and
an analog-to-digital converter configured to convert output currents from the array of programmable resistive memory elements to digital values;
a memory array coupled to the DPE core and configured to store the digital input vectors and the digital values; and
control circuitry configured to implement pipeline stages comprising read, compute, sum, activation, write operations, or combinations thereof, for coordinating data flow between the memory array, the DPE core, and the configurable logic circuit.

9. The field programmable gate array of claim 8, wherein the DPE core further comprises:
an input buffer coupled to the digital-to-analog converter and configured to temporarily store the digital input vectors; and
an output buffer coupled to the analog-to-digital converter and configured to temporarily store the digital values.

10. The field programmable gate array of claim 8, wherein the array of programmable resistive memory elements comprises:
a plurality of row lines;
a plurality of column lines; and
memristor elements positioned at crossbar junctions where the row lines and column lines intersect.

11. The field programmable gate array of claim 8, wherein the DPE core further comprises shift and add circuitry configured to:
perform bit shift operations on the digital values; and
accumulate the shifted digital values to construct higher precision results.

12. The field programmable gate array of claim 8, wherein the configurable logic circuit comprises look-up tables configured to:
implement activation functions between matrix computations; and
perform pooling operations for reducing data dimensionality.

13. The field programmable gate array of claim 8, wherein the control circuitry is further configured to:
apply first voltages to program resistance values of the programmable resistive memory elements; and
apply second voltages representing the digital input vectors to perform the matrix-vector multiplication.

14. The field programmable gate array of claim 8, wherein the pipeline stages are configured to:
read the digital input vectors from the memory array;
compute the matrix-vector multiplication using the DPE core;
sum partial results from the DPE core;
apply activation functions using the configurable logic circuit;
write the digital values to the memory array; or a combination thereof.

15. A method of implementing a neural network in a field programmable gate array, the method comprising:
dividing a neural network model into multiple layers, wherein an architecture of the neural network model is defined using a high-level model description;
determining hardware resource allocation for the multiple layers within the field programmable gate array, wherein the hardware resource allocation maps input sizes to memory sizes and filter sizes to a number of analog dot product engine (DPE) cores integrated within the field programmable gate array;
generating intermediate code for pipeline stages;
converting the intermediate code into a hardware description language implementation for configuring the field programmable gate array; and
programming resistive memory elements within the DPE cores with matrix weights for performing matrix-vector multiplication in an analog domain.

16. The method of claim 15, wherein the pipeline stages comprise:
reading digital input vectors from a memory array of the field programmable gate array;
computing matrix-vector multiplication using the DPE cores;
summing partial results from the DPE cores;
applying activation functions using configurable logic circuits of the field programmable gate array;
writing digital values to the memory array; or a combination thereof.

17. The method of claim 15, wherein determining the hardware resource allocation comprises:
mapping input vector sizes to input memory sizes;
mapping filter sizes and stride sizes to a number of DPE cores; and
mapping output sizes to output memory sizes.

18. The method of claim 15, wherein programming the resistive memory elements comprises:
applying first voltages to program resistance values corresponding to the matrix weights; and
applying second voltages representing digital input vectors to perform the matrix-vector multiplication.

19. The method of claim 15, further comprising:
converting digital input vectors to analog voltages using digital-to-analog converters within the DPE cores;
performing matrix-vector multiplication in an analog domain using the programmed resistive memory elements; and
converting output currents to digital values using analog-to-digital converters within the DPE cores.

20. The method of claim 15, further comprising:
performing bit shift operations on digital values output from the DPE cores; and
accumulating the shifted digital values to construct higher precision results.
